(19) United States
(12) Patent Application Publication
(10) Pub. No.: US 2022/0329228 A1
(43) Pub. Date: Oct. 13, 2022

(54) ELASTIC WAVE DEVICE AND METHOD OF MANUFACTURING ELASTIC WAVE DEVICE

(71) Applicant: KYOCERA Corporation, Kyoto-shi, Kyoto (JP)

(72) Inventor: Masaki NAMBU, Katano-shi, Osaka (JP)

(21) Appl. No.: 17/621,634

(22) PCT Filed: Jun. 26, 2020
(86) PCT No.: PCT/JP2020/025204

§ 371 Date: Dec. 21, 2021

(30) Foreign Application Priority Data
Jun. 28, 2019 (JP) 2019-121208

(51) Int. Cl. H03H 9/10; H03H 3/08; H03H 9/05; H03H 9/25

(52) U.S. Cl. CPC H03H 9/1092; H03H 3/08; H03H 9/059; H03H 9/25

(57) ABSTRACT

In an elastic wave device, a substrate includes a piezoelectric predetermined region in a first main surface facing one side in a normal direction of the substrate. An excitation electrode is positioned on the predetermined region. A cover covers the excitation electrode and the first main surface from the one side. A surrounding portion covers a side surface of the substrate and a side surface of the cover, and has insulating properties. A wiring layer includes an external terminal exposed toward the one side, and overlaps the cover and the surrounding portion from the one side. A connection conductor connects the excitation electrode and the external terminal to each other. The connection conductor includes a first portion extending to the external terminal from a position that is closer to the substrate than an upper surface of the cover on the one side. The first portion has a melting point higher than or equal to 450° C.

### TECHNICAL FIELD

The present disclosure relates to an elastic wave device and a method of manufacturing an elastic wave device. An elastic wave is, for example, a surface acoustic wave (SAW).

### BACKGROUND ART

So-called wafer level package (WLP) elastic wave chips are known (see, for example, PTLs 1 to 3). A WLP elastic wave chip includes, for example, a piezoelectric substrate, an excitation electrode that is positioned on an upper surface of the piezoelectric substrate, a cover that covers the upper surface of the piezoelectric substrate from above the excitation electrode, and a terminal that is positioned on an upper surface of the cover and that is electrically connected to the excitation electrode.

The WLP elastic wave chip described above, which is packaged by the cover and the like, may be further packaged to form an elastic wave device (see, for example, PTLs 1 to 3). The specifics are as follows. In the following description, the term “main surface” refers to, for example, the largest surface of a plate-shaped member. That is, the term “main surface” refers to the front surface or the back surface of the plate-shaped member. The same applies hereafter.

First, an elastic wave chip is mounted on a rigid interposer (circuit board). To be specific, the elastic wave chip is placed in such a way that an upper surface of a cover and one main surface of the interposer face each other, and a terminal that is positioned on the upper surface of the cover and a pad that is positioned on the one main surface of the interposer are joined to each other by using solder. Note that the interposer has an external terminal, which is electrically connected to the pad on the one main surface, on the other main surface. Next, a resin in an uncured state is placed on the one main surface of the interposer (from a different viewpoint, around the elastic wave chip), and the resin is cured. Thus, an elastic wave device, in which the WLP elastic wave chip is further packaged, is fabricated.

### CITATION LIST

### Patent Literature

PTL 1: International Publication No. 2008/069567

PTL 2: Japanese Unexamined Patent Application Publication No. 2010-278972

PTL 3: Japanese Unexamined Patent Application Publication No. 2018-74566

### SUMMARY OF INVENTION

An elastic wave device according to an aspect of the present disclosure includes a substrate, an excitation electrode, an insulating cover, a surrounding portion, a wiring layer, and a connection conductor. The substrate includes a piezoelectric predetermined region in a first main surface facing one side in a normal direction of the substrate. The excitation electrode is positioned on the predetermined region. The cover covers the excitation electrode and the first main surface from the one side. The surrounding portion covers a side surface of the substrate and a side surface of the cover. The wiring layer includes an external terminal exposed toward the one side, and overlaps the cover and the surrounding portion from the one side. The connection conductor electrically connects the excitation electrode and the external terminal to each other. The connection conductor includes a first portion extending to the external terminal from a position that is closer to the substrate than a surface of the cover on the one side, the first portion having a melting point higher than or equal to 450° C.

In a method of manufacturing an elastic wave device according to an aspect of the present disclosure, the elastic device includes a chip, a surrounding portion, and a wiring layer. The chip includes a substrate, an excitation electrode, and an insulating cover. The substrate includes a piezoelectric predetermined region in a first main surface facing one side in a normal direction of the substrate. The excitation electrode is positioned on the predetermined region. The cover covers the excitation electrode and the first main surface from the one side. The surrounding portion covers a side surface of the substrate and a side surface of the cover, and has insulating properties. The wiring layer includes an external terminal electrically connected to the excitation electrode. The external terminal is exposed toward the one side. The wiring layer overlaps the cover and the surrounding portion from the one side. The method includes: a chip fabrication step of fabricating the chip; a surrounding-portion fabrication step of fabricating the surrounding portion by placing an insulating material in an uncured state around the chip and curing the insulating material after the chip fabrication step; and a wiring-layer placement step of providing the wiring layer on the one side of the cover and the surrounding portion after the surrounding-portion fabrication step.

### BRIEF DESCRIPTION OF DRAWINGS

FIG. 1 is a sectional view illustrating the configuration of a SAW device according to an embodiment.

FIG. 2 is a sectional view of a SAW chip included in the SAW device of FIG. 1.

FIG. 3 is a plan view illustrating an excitation electrode of the SAW chip of FIG. 2.

FIG. 4 is a schematic sectional view illustrating a part of the SAW chip of FIG. 2.

FIG. 5 is a flowchart illustrating an example of the steps of a method of manufacturing the SAW device of FIG. 1.

FIGS. 6(a) to 6(e) are sectional views supplemental to the flowchart of FIG. 5.

FIG. 7 is a schematic circuit diagram illustrating the configuration of a multiplexer including the SAW device.

FIG. 8 is a block diagram illustrating a main part of a communication apparatus that is an application example of the SAW device.

FIG. 9(a) is a sectional view illustrating a SAW chip according to a first modification, and FIG. 9(b) is a sectional view illustrating a SAW chip according to a second modification.

FIGS. 10(a) and 10(b) are sectional views respectively illustrating a part of a SAW device according to a third modification and a part of a SAW device according to a fourth modification.

### DESCRIPTION OF EMBODIMENTS

Hereafter, an embodiment according to the present disclosure will be described with reference to the drawings. The drawings used in the following description are schematic, and dimensional ratios and the like do not necessarily coincide with actual ones.

Regarding a SAW device according to the present disclosure, whichever direction may be defined as an upward direction or a downward direction. For convenience, in the following description, an orthogonal coordinate system having a D1 axis, a D2 axis, and a D3 axis is defined, and, assuming that the positive side of the D3 axis is upward, terms such as “upper surface” or “lower surface” may be used. The D1 axis is defined to extend in the propagation direction of a SAW that propagates along an upper surface of a piezoelectric body (described below), the D2 axis is defined to be parallel to the upper surface of the piezoelectric body and perpendicular to the D1 axis, and the D3 axis is defined to be perpendicular to the upper surface of the piezoelectric body. Unless otherwise noted, the term “plan view’ or “see-through plan view” refers to a view when seen in the D3 direction.

### SAW Device

### Overall Structure

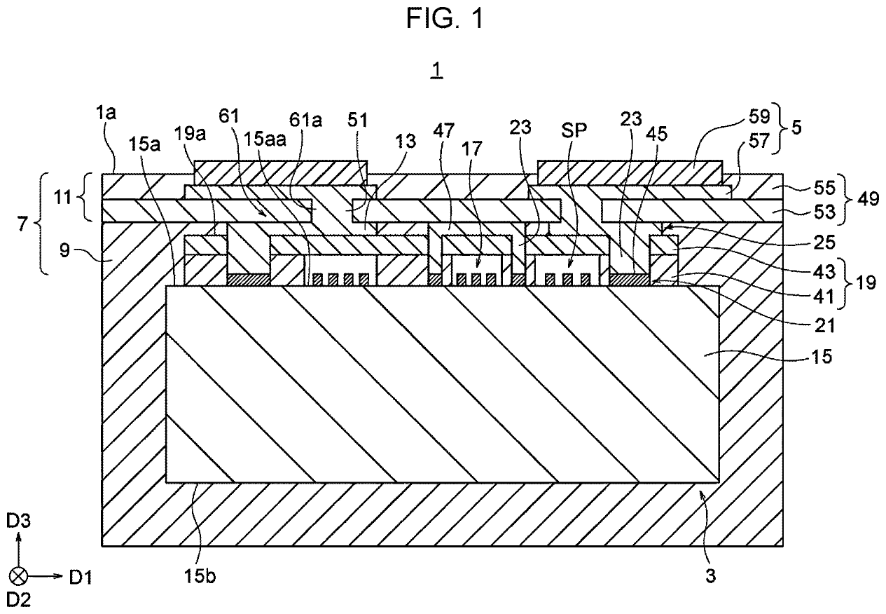

FIG. 1 is a sectional view of a SAW device 1 (an example of an elastic wave device) according to an embodiment.

The SAW device 1 is generally shaped like, for example, a thin rectangular parallelepiped whose thickness direction is the D3 direction. FIG. 1 illustrates a cross section that is, for example, parallel to one of four side surfaces (surfaces extending in the D3 direction) of the rectangular parallelepiped. The size of the SAW device 1 may be set in any appropriate manner. As an example, the length of one side of the SAW device 1 in plan view is greater than or equal to 1 mm and less than or equal to 5 mm, and the thickness of the SAW device 1 is greater than or equal to 0.3 mm and less than or equal to 1 mm.

The SAW device 1 is configured as, for example, an electronic component to be surface-mounted on a circuit board or the like (not illustrated). To be specific, for example, the SAW device 1 includes a plurality of external terminals 5 that are exposed from an upper surface 1a facing the +D3 side. The SAW device 1 is to be placed, for example, in such a way that the upper surface 1a faces a circuit board (not illustrated), and is to be mounted on the circuit board by joining the external terminals 5 to pads of the circuit board via bumps composed of solder or the like. For example, the SAW device 1 receives input of an electric signal through one of the plurality of external terminals 5, performs predetermined processing on the electric signal, and outputs the electric signal from another of the plurality of external terminals 5.

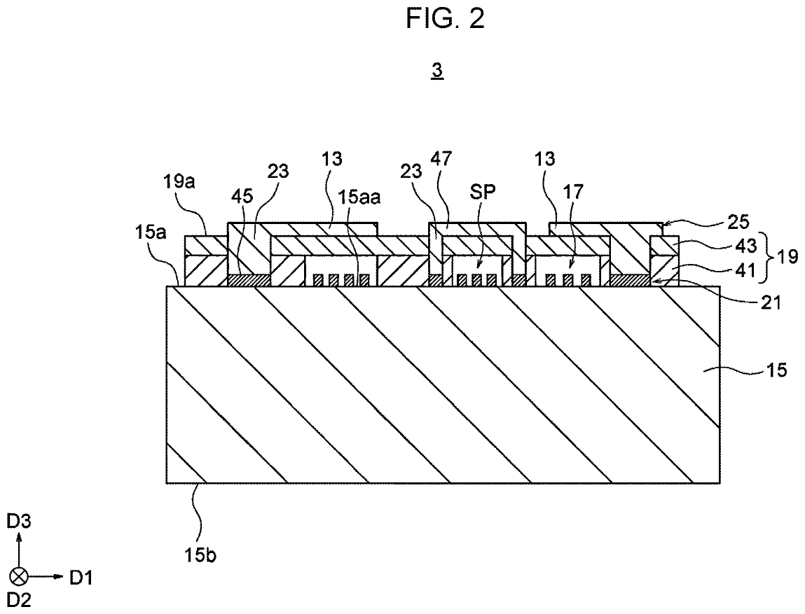

FIG. 2 is a sectional view, corresponding to a part of FIG. 1, of a SAW chip 3 (hereafter, simply referred to as “chip 3”) included in the SAW device 1.

As illustrated in FIG. 1 and FIG. 2, the SAW device 1 includes, for example, the chip 3 and a package 7 packaging the chip 3. For example, the chip 3 directly and/or predominantly performs signal processing. The package 7 contributes to protection of the chip 3 and/or electric connection between the chip 3 and the outside (the aforementioned circuit board (not illustrated)).

The package 7 includes a surrounding portion 9 that covers most of the surfaces of the chip 3, and a wiring layer 11 that overlaps the chip 3 and the surrounding portion 9 on the +D3 side. The surrounding portion 9 mainly contributes to, for example, protection of the chip 3. The wiring layer 11 includes the aforementioned external terminals 5 and, for example, electrically connects the chip 3 to the outside. Naturally, the wiring layer 11 may contribute to protection of the chip 3.

In the illustrated example, the SAW device 1 includes only one chip 3. Although not particularly illustrated, the SAW device 1 may include a plurality of SAW chips 3 that are packaged together by the package 7 or may include one or more SAW chips 3 and a chip of another type (such as an integrated circuit (IC)). The plurality of chips are arranged, for example, along the wiring layer 11 (the D1-D2 plane).

### Overall Configuration of Chip

For example, basically, the chip 3 need not be packaged by the package 7 and may have a configuration similar to that of a WLP SAW chip that can be surface-mounted on a circuit board (not illustrated) or the like. However, because the chip 3 is packaged by the package 7, the chip 3 may have a configuration (structure, dimensions, and/or material) that is different from that of a WLP SAW chip that is mounted as a single unit. For example, a member for reinforcement may be made thinner, and a conductor for connection with the outside may be made smaller.

The chip 3 is generally shaped like, for example, a thin rectangular parallelepiped whose thickness direction is the D3 direction. FIGS. 1 and 2 illustrate a cross section that is, for example, parallel to one of four side surfaces (surfaces extending in the D3 direction) of the rectangular parallelepiped. The chip 3 includes, for example, a plurality of chip terminals 13 that are exposed from an upper surface 19a facing the +D3 side. For example, the chip 3 receives input of an electric signal through one of the plurality of chip terminals 13, performs predetermined processing on the electric signal, and outputs the electric signal from another of the plurality of chip terminals 13.

The chip 3 includes a substrate 15, an excitation electrode 17 that is positioned on a first main surface 15a of the substrate 15, and a cover 19 that covers the first main surface 15a from above the excitation electrode 17. When a voltage is applied to the substrate 15 through the excitation electrode 17, the first main surface 15a vibrates, and, by extension, a SAW is excited. By utilizing the SAW, for example, processing on a signal that is input to the chip 3 is performed. The cover 19 contributes to, for example, allow the first main surface 15a to vibrate easily by forming a space SP on the excitation electrode 17.

The chip 3 further includes, for example, a first conductor layer 21 that is positioned on the first main surface 15a, a plurality of first via conductors 23 that extend through the cover 19 in the D3 direction, and a second conductor layer 25 that is positioned on the upper surface 19a of the cover 19. The first conductor layer 21 includes, for example, the excitation electrode 17. The second conductor layer 25 includes, for example, the chip terminals 13. The plurality of first via conductors 23 contribute to, for example, conduction between the first conductor layer 21 and the second conductor layer 25. Although not particularly illustrated, the chip 3 may further include a conductor layer that is positioned in (embedded in) the cover 19 and that is parallel to the first main surface 15a.

The chip 3 may further include other various constituent elements (not illustrated). For example, the chip 3 may include an insulating protective film (such as a SiO2 film) that covers most of the first conductor layer 21 (such as the excitation electrode 17). The protective film may be a comparatively thin film for only protecting the first conductor layer 21 from corrosion or the like, or may be a comparatively thick film that contributes to temperature compensation of the chip 3. For example, the chip 3 may include a back-side electrode that covers a surface of the substrate 15 on the −D3 side (a second main surface 15b), or may include an insulating film that covers the back-side electrode. For example, the chip 3 may include an insulating film that covers a side surface of the substrate 15 (a surface along the D3 axis) and/or a side surface of the cover 19 (a surface along the D3 axis). For example, the chip 3 may include an insulating film that covers a partial region of the second conductor layer 25.

### Substrate

The shape of the substrate 15 may be set in any appropriate manner. For example, the shape of the substrate 15 is, generally, a thin rectangular parallelepiped whose thickness direction is the D3 direction. FIGS. 1 and 2 illustrate a cross section that is, for example, parallel to one of four side surfaces (surfaces extending in the D3 direction) of the rectangular parallelepiped. The substrate 15 has piezoelectric properties at least in a predetermined region 15aa of the first main surface 15a on which the excitation electrode 17 is disposed.

Examples of the substrate 15 having piezoelectric properties in the predetermined region 15aa include a substrate the entirety of which is formed of a piezoelectric body (that is, a piezoelectric substrate). Examples of the substrate 15 further includes a so-called bonded substrate. The bonded substrate includes a substrate (piezoelectric substrate) that is formed of a piezoelectric body having the first main surface 15a, and a support substrate that is bonded, by using adhesive or by not using an adhesive and directly, to a surface of the piezoelectric substrate opposite to the first main surface 15a. Examples of the substrate 15 having piezoelectric properties in the predetermined region 15aa includes a substrate including: a support substrate; and a film (piezoelectric film), formed of a piezoelectric body, or a multi-layer film, including a piezoelectric film, that is formed on a part or the entirety of a main surface of the support substrate on the +D3 side.

The piezoelectric body that forms at least the predetermined region 15aa of the substrate 15 is formed of, for example, a single crystal having piezoelectric properties. Examples of a material that forms such a single crystal include lithium tantalate (LiTaO₃), lithium niobate (LiNbO₃), and quartz (SiO₂). Cut angles, planar shape, and various dimensions may be set in any appropriate manner.

The substrate 15 may include a stepped portion in the first main surface 15a, although such a configuration differs from the illustrated example. For example, in the aforementioned configuration in which a piezoelectric film is formed on the main surface of the support substrate, a region of the first main surface 15a formed of the piezoelectric film may be higher than a region of the first main surface 15a formed of the main surface of the support substrate. The substrate 15 may include a protruding part in a side surface thereof, or a side surface of the substrate 15 may be inclined in an orientation such that the substrate 15 widens or narrows toward the —D3 side, although such a configuration differs from the illustrated example.

### Excitation Electrode and Conductors Therearound

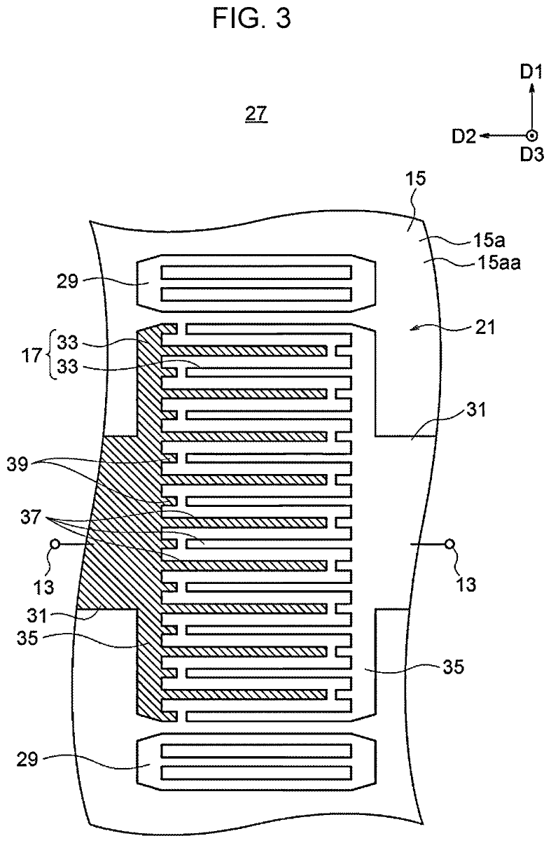

FIG. 3 is a schematic plan view illustrating the excitation electrode 17. This figure is a plan view of a part of the predetermined region 15aa of the substrate 15 when seen from above the excitation electrode 17.

In the illustrated example, the excitation electrode 17 is formed of a so-called interdigital transducer (IDT) electrode. In the illustrated example, the excitation electrode 17 is combined with a pair of reflectors 29 to form a so-called single-port SAW resonator 27. For example, when an electric signal of a predetermined frequency is input from one of the two chip terminals 13 (schematically illustrated), the SAW resonator 27 causes resonance and outputs a signal that has caused the resonance from the other of the two chip terminals 13. FIG. 3 also illustrates wiring 31 connected to the excitation electrode 17.

The excitation electrode 17, the reflectors 29, and the wiring 31 constitute the aforementioned first conductor layer 21 on the first main surface 15a. The material of the first conductor layer 21 will be described below. The thicknesses of the excitation electrode 17, each reflector 29, and the like may be set in any appropriate manner in accordance with the electric characteristics and the like required for the SAW chip 3. Although not particularly illustrated, on an upper surface or a lower surface of the excitation electrode 17 and/or the reflector 29, an additional film made of an insulator or a metal may be disposed in order to improve the reflection coefficient of a SAW.

The excitation electrode 17 includes a pair of interdigital electrodes 33. In FIG. 3, for the sake of visibility, one of the pair of interdigital electrodes 33 and the wiring 31 connected to the interdigital electrode 33 are hatched. Each interdigital electrode 33 includes, for example, a busbar 35, a plurality of electrode fingers 37 that extend from the busbar 35 parallel to each other, and a plurality of dummy electrodes 39 that protrude from the busbar 35 between the plurality of electrode fingers 37. The pair of interdigital electrodes 33 are disposed in such a way that the plurality of electrode fingers 37 mesh with each other (cross each other). In the sectional views of FIGS. 1 and 2, the electrode fingers 37 of the excitation electrode 17 are schematically illustrated.

When a voltage is applied to the pair of interdigital electrodes 33, the voltage is applied by the electrode fingers 37 to the predetermined region 15aa, and a SAW in a predetermined mode that propagates in the D1-axis direction is excited. The excited SAW is mechanically reflected by the electrode fingers 37. As a result, a standing wave whose half-wavelength is equal to the pitch of the electrode fingers 37 is formed. The reflectors 29 reduce leakage of the SAW that forms the standing wave. The standing wave is converted into an electric signal having the same frequency as the standing wave and is taken out by the electrode fingers 37. In this way, the SAW resonator 27 functions as a resonator. The resonant frequency of the SAW resonator 27 is approximately equal to the frequency of a SAW that propagates in the predetermined region 15aa with a half-wavelength that is equal to the pitch of the electrode fingers.

FIG. 3 only schematically illustrates an example of the configuration of the excitation electrode 17, and the configuration of the excitation electrode 17 may be set and/or modified in any appropriate manner. For example, the number and various dimensions of the electrode fingers 37 may be set in any appropriate manner. The pitch of the electrode fingers 37 may be constant, may vary slightly, or may include an irregular pitch (such as a narrow-pitch portion) in a part thereof. The busbar (without reference numeral), which connects the plurality of electrode fingers 37, may extend in the D1 direction, or may be inclined with respect to the D1 direction, although such a configuration differs from the illustrated example. The excitation electrode 17 need not include the dummy electrodes 39. The distance between the tips of two adjacent electrode fingers in the D2 direction (so-called crossing width) may be constant as in the illustrated example, or may be different in accordance with the position in the D1 direction (so-called apodised). There may be a part where a small number of electrode fingers 37 are substantially omitted.

As described below, the chip 3 may include a ladder filter composed of a plurality of SAW resonators 27. The excitation electrode 17 need not constitute the SAW resonator 27. Instead, a plurality of excitation electrodes 17 may be arranged between a pair of reflectors 29 in the D1 axis direction to form a multi-mode (including a double-mode in the present disclosure) resonator filter.

### Cover

Referring back to FIGS. 1 and 2, the outer shape of the cover 19 (a shape disregarding the space SP and the like) may be set in any appropriate manner. For example, the outer shape of the cover 19 is, generally, a thin rectangular parallelepiped whose thickness direction is the D3 direction. FIGS. 1 and 2 illustrate a cross section that is, for example, parallel to one of four side surfaces (surfaces extending in the D3 direction) of the rectangular parallelepiped. The cover 19 is, for example, slightly smaller than the first main surface 15a of the substrate 15 in plan view, and allows the outer edge of the first main surface 15a to be exposed around the entire periphery of the cover 19.

The cover 19 includes, for example, a frame portion 41 having a frame-like shape in plan view, and a cover portion 43 that covers an opening of the frame portion 41. As the opening of the frame portion 41 is covered by the cover portion 43, a closed space SP is formed. The inside of the space SP may be, for example, in a vacuum state (to be precise, a depressurized state), or may be filled with any appropriate gas (such as nitrogen). When the space SP is filled with a gas, the pressure of the gas may be lower than, about the same as, or higher than the atmospheric pressure.

The frame portion 41 is, for example, a generally-constant-thickness layer in which an opening that serves as the space SP is formed. The thickness of the frame portion 41 in the D3 direction (the height of the space SP) is, for example, greater than or equal to 5 μm and less than or equal to 30 μm. The cover portion 43 is, for example, a generally-constant-thickness layer that is stacked on the frame portion 41. The thickness of the cover portion 43 (in the D3 direction) is, for example, greater than or equal to 5 μm and less than or equal to 30 μm. The thickness of the frame portion 41 and the thickness of the cover portion 43 may be the same as each other or may be different from each other. The thickness of the frame portion 41 in plan view (in the D1 direction or the D3 direction, the thickness of a wall) may be set in any appropriate manner.

The frame portion 41 and the cover portion 43 may be made of the same material or may be made of materials that are different from each other. In FIGS. 1 and 2, for convenience of description, the boundary line between the frame portion 41 and the cover portion 43 is clearly illustrated. However, in an actual product, the frame portion 41 and the cover portion 43 may be integrally formed from the same material. The frame portion 41 and the cover portion 43 each may be composed of a plurality of layers.

The cover 19 (the frame portion 41 and the cover portion 43) is basically made of an insulating material. The insulating material is, for example, a photosensitive resin. The photosensitive resin is, for example, a resin that cures due to radical polymerization of an acrylic group, a methacrylic group, or the like. Examples of such a resin include a urethane acrylate resin, a polyester acrylate resin, and an epoxy acrylate resin.

### Various Conductors in Chip

As described above, the first conductor layer 21 includes, for example, the excitation electrode 17, the reflectors 29, and the wiring 31. The first conductor layer 21 further includes, for example, an internal terminal 45 that is connected to the excitation electrode 17 via the wiring 31. The internal terminal 45 is, for example, a part that is directly connected to the first via conductor 23. The first conductor layer 21 may further include, for example, a pattern that forms electric components such as inductors and/or capacitors.

The materials and thicknesses of various parts included in the first conductor layer 21 may be the same as each other, or the materials and/or the thicknesses may be different from each other. Various parts of the first conductor layer 21 may be composed of one metal layer, or may be composed of a plurality of metal layers made of materials that are different from each other. For example, the excitation electrode 17, the reflectors 29, and the wiring 31 may be formed of first layers that are made of the same material and that have the same thickness; and the internal terminal 45 may be composed of the first layer and a second layer that overlaps the first layer and that is made of a material different from that of the first layer. The first layer and the second layer each may be composed of two or more metal layers. Examples of the material of the entirety of the first layer, the material of 80% or more of the thickness of the first layer, or the material of 50% or more of the thickness of the first layer include Al and an alloy containing Al as a main component. Examples of the alloy include an Al—Cu alloy. The term “main component” refers to, for example, a component occupying 50 mass % or greater or 80 mass % or greater (the same applies hereafter).

The number of the internal terminals 45 may be set in any appropriate manner in accordance with the configuration and the like of a circuit formed of the excitation electrode 17. The shape and dimensions of the internal terminal 45 may be set in any appropriate manner. For example, the planar shape of the internal terminal 45 may be a circle. The boundary between the internal terminal 45 and the wiring 31 need not be clear. The position of the internal terminal 45 also may be set in any appropriate manner. For example, the internal terminal 45 may be disposed at a position adjacent to an outer peripheral edge of the first main surface 15a of the substrate 15 (for example, a position such that the shortest distance from the outer peripheral edge to the internal terminal 45 is less than or equal to the diameter of the internal terminal 45), or may be disposed at a position farther than the above position.

Each of the first via conductors 23 has, for example, a columnar shape extending through at least a part of the thickness of the cover 19, is directly connected to at least one of the internal terminal 45 and the second conductor layer 25, and contributes to electric connection between these two. In the illustrated example, the first via conductor 23 extends through substantially the entire thickness of the cover 19 (the frame portion 41 and the cover portion 43), and is directly connected to both of the internal terminal 45 and the second conductor layer 25. Examples of a configuration other than the illustrated example, which is not particularly illustrated, include the following configuration: a first via conductor 23 that extends through the frame portion 41 and that is connected to the internal terminal 45 and a first via conductor 23 that extends through the cover portion 43 and that is connected to the second conductor layer 25 are provided, and these two first via conductors 23 are connected to each other by a conductor layer between the frame portion 41 and the cover portion 43.

The specific shape and dimensions of each first via conductor 23 may be set in any appropriate manner. For example, the shape of a cross section of the first via conductor 23 parallel to the first main surface 15a may be a circle or an ellipse. For example, the diameter of the first via conductor 23 may be constant or need not be constant in the extension direction. Examples of the latter include a tapered shape, an inversely tapered shape, and/or a shape such that the diameter of a part extending through the frame portion 41 and the diameter of a part extending through the cover portion 43 are different from each other. The dimensions and/or the materials of the plurality of first via conductors 23 may be the same as each other or may be different from each other.

The material of the first via conductor 23 may be any appropriate metal. The entirety of the first via conductor 23 may be made of the same material, or parts of the first via conductor 23 may be made of materials that are different from each other. Examples of the latter include a configuration such that the first via conductor 23 includes: an underlying layer formed on an inner surface of a hole of the cover 19, and a body portion formed by electric plating or the like on the inside of the underlying layer. In this case, only the body portion may be regarded as the first via conductor 23. The material of the first via conductor 23 may be the same as or different from the material of the first conductor layer 21. Examples of the material in the latter case include a material having a higher electroconductivity (lower electric resistivity) than the material of a main part of the first conductor layer 21 (such as the excitation electrode 17) that is selected in consideration of an acoustic viewpoint. For example, in the aforementioned case where the material of the first conductor layer 21 is Al or an alloy containing Al as a main component, the material of the first via conductor 23 may be Cu or an alloy containing Cu as a main component.

The second conductor layer 25 includes, for example, the chip terminals 13 as described above. The second conductor layer 25 includes, for example, wiring (without reference numeral) that connects the first via conductors 23 and the chip terminals 13, and an appropriate conductor pattern 47.

The chip terminals 13 are, for example, electrically connected to the excitation electrode 17 via the first via conductors 23 and the internal terminals 45. The number of the chip terminals 13 may be set in any appropriate manner in accordance with the configuration of a circuit in the chip 3. The number of the chip terminals 13 may be the same as or different from the number of the internal terminals 45. The shape and dimensions of each chip terminal 13 may be set in any appropriate manner. For example, the planar shape of each chip terminal 13 may be a circle. The boundary between the chip terminal 13 and wiring included in the second conductor layer 25 need not be clear.

The position of the chip terminal 13 in the upper surface 19a of the cover 19 may be set in any appropriate manner. For example, in a see-through plan view, the chip terminal 13 may overlap the entirety of the internal terminal 45 and/or the first via conductor 23, or need not overlap a part or the entirety of the internal terminal 45 and/or the first via conductor 23. For example, in a see-through plan view, a part or the entirety of the chip terminal 13 may overlap the space SP, or the entirety of the chip terminal 13 need not overlap the space SP.

The specific configuration of connection between the chip terminal 13 and the internal terminal 45 may be set in any appropriate manner. For example, the chip terminal 13 may be electrically connected to the internal terminal 45 directly below the chip terminal 13 by being directly connected to the first via conductor 23 positioned directly below the chip terminal 13. The chip terminal 13 may be electrically connected to the internal terminal 45 that is not positioned directly below the chip terminal 13 by being electrically connected to the first via conductor 23 that is not positioned directly below the chip terminal 13 through wiring or the like (not illustrated) included in the second conductor layer 25. The chip terminal 13 may be electrically connected to the internal terminal 45 that is not positioned directly below the chip terminal 13 via a conductor layer (not illustrated) embedded in the cover 19.

Examples of the conductor pattern 47 include a reinforcement layer that contributes to reinforcement of the cover portion 43. The shape and dimensions of the reinforcement layer in plan view may be set in any appropriate manner. For example, in a see-through plan view, the reinforcement layer may cover the entirety of the space SP, may cover a part of the space SP, or may extend across the boundary between the inside and outside of the space SP. The reinforcement layer may be, for example, in an electrically floating state (a state of having no electric potential), or may be provided with a reference potential. The reinforcement layer may be connected to or need not be connected to the first via conductor 23. In the former case, the reinforcement layer is supported by the first main surface 15a via the first via conductor 23.

Examples of the conductor pattern 47 include a pattern that forms electric elements such as inductors and/or capacitors. Such an electronic element may be connected, for example, to the internal terminal 45 via the first via conductor 23, and/or may be connected to the chip terminal 13 via wiring (not illustrated) included in the second conductor layer 25. By extension, the electronic element may be electrically connected to the excitation electrode 17.

The materials and thicknesses of various parts included in the second conductor layer 25 may be the same as each other, or the materials and/or thicknesses may be different from each other. Various parts of the second conductor layer 25 each may be composed of a single metal layer, or each may be composed of a plurality of metal layers that are made of materials that are different from each other. For example, the second conductor layer 25 may include, although not particularly illustrated, an underlying layer that is positioned on the upper surface 19a of the cover 19 (excluding areas directly above the first via conductors 23), and a body portion formed on the underlying layer by electric plating or the like. The material (of the entirety or the body portion) of the second conductor layer 25 may be, for example, as with the first via conductors 23, a material having a higher electroconductivity (lower electric resistivity) than the material of a main part of the first conductor layer 21 (such as the excitation electrode 17). To be specific, the material may be Cu or an alloy containing Cu as a main component.

The material of the second conductor layer 25 may be the same as or different from the material of the first via conductors 23. Examples of the former include the following configuration: the first via conductors 23 and the second conductor layer 25 are both formed of an underlying layer, which extends over the upper surface 19a from an inner surface of a hole of the cover 19 in which the first via conductors 23 is disposed, and a metal material (body) precipitated on the underlying layer.

The second conductor layer 25 does not include an increased-width portion in the thickness direction (the D3 direction). In other words, the width the second conductor layer 25 does not change in such a way that the width has the maximum value near the center in the thickness direction. Thus, a short circuit between the second conductor layers 25 that are adjacent to each other in plan view can be suppressed. Moreover, strength of joint with the surrounding portion 9 is increased, peeling-off can be reduced, and the reliability can be increased. Furthermore, variation in electric characteristics due to a change in width in the thickness direction can be suppressed.

The thickness of the second conductor layer 25 may be smaller than the thickness of the frame portion, the cover portion, and first and second insulating layers (described below). Thus, the distance between the chip and the wiring layer can be reduced.

### Surrounding Portion

The surrounding portion 9 illustrated in FIG. 1 covers, for example, the entirety of the chip 3, excluding the upper surface of the second conductor layer 25 of the chip 3. To be specific, the surrounding portion 9 covers all of the (here, four) side surfaces of the chip 3. That is, the surrounding portion 9 covers all of the side surfaces of the substrate 15, and covers all of the side surfaces of the cover 19. The surrounding portion 9 covers, for example, the entirety of the lower surface of the chip 3 (a surface on the −D3 side, the second main surface 15b of the substrate 15). The surrounding portion 9 covers, for example, a region of the upper surface 19a of the cover 19 on which the second conductor layer 25 is not disposed. The surrounding portion 9 covers a part of the first main surface 15a of the substrate 15 closer to the outer periphery than the cover 19.

As described above, one SAW device 1 may include a plurality of chips (such as the chips 3) that are arranged along the wiring layer 11. In this case, the surrounding portion 9 covers the entirety of the plurality of chips so that the plurality of chips are not exposed to the outside. However, the spaces between the chips 3 that are adjacent to each other may be filled with the surrounding portion 9 without a gap, or the spaces that are in a vacuum state or filled with a gas may be formed between the chip 3.

The surrounding portion 9 may be in direct and close contact with various surfaces, such as the side surfaces of the substrate 15, the second main surface 15b, and the side surfaces of the cover 19; or may be in close contact with another member (layer) that is in contact with various surfaces to indirectly cover the various surfaces. For example, as described above, the chip 3 may include a back-side electrode that overlaps the second main surface 15b and an insulating layer that covers the back-side electrode, and the surrounding portion 9 may cover the second main surface 15b by being in close contact with the insulating layer. Likewise, in the present disclosure, regarding other members and surfaces, the meaning of the term “cover” (or “overlap” or the like) includes not only “directly cover” but also “indirectly cover”.

The surrounding portion 9 forms the outer shape of the SAW device 1 together with the wiring layer 11, and forms most of the outer shape of the SAW device 1 on the −D3 side. The outer shape of the surrounding portion 9, which forms the outer shape of the SAW device 1, may be set in any appropriate manner. In the illustrated example, as can be understood from the description of the entirety of the SAW device 1, the outer shape of the surrounding portion 9 is, generally, a thin rectangular parallelepiped whose thickness direction is the D3 direction. However, for example, the surrounding portion 9 may include a protruding portion on a side surface, or a side surface of the surrounding portion 9 may be inclined in an orientation such that the SAW device 1 widens or narrows toward the −D3 side, although such a configuration differs from the illustrated example. For example, a side surface of the surrounding portion 9 may be parallel to (as in the illustrated example) or need not be parallel to a side surface the substrate 15 and/or a side surface of the cover 19.

Various dimensions of the surrounding portion 9 may be set in any appropriate manner. For example, the thickness (in the D1 direction or the D2 direction) of a part that covers a side surface of the substrate 15 and a side surface of the cover 19 and the thickness (in the D3 direction) of a part of the surrounding portion 9 that covers the second main surface 15b may be approximately the same as each other or may be considerably different from each other. The thicknesses of parts that cover the four side surfaces of the substrate 15 and the four side surfaces of the cover 19 may be approximately the same as each other or may be different from each other.

For example, the entirety of the surrounding portion 9 is integrally formed from the same material. The material of the surrounding portion 9 is, for example, an insulating material. The insulating material may be an organic material or may be an inorganic material. For example, the entirety of the surrounding portion 9 or the base material of the surrounding portion 9 is made of a resin. The resin may be, for example, a thermosetting resin. Examples of the thermosetting resin include an epoxy resin and a phenol resin. A filler composed of insulating particles may be mixed in the resin. The insulating particles may be made of, for example, a material having a lower thermal expansion coefficient than the resin. The material of the insulating particles may be, for example, silica, alumina, phenol, polyethylene, glass fiber, or graphite.

### Wiring Layer

The wiring layer 11 illustrated in FIG. 1 covers the upper surface 19a of the cover 19, the upper surface of the second conductor layer 25, and the upper surface of the surrounding portion 9. In plan view, the wiring layer 11 has, for example, a shape and a size with which the wiring layer 11 can exactly cover the entirety of the above three surfaces. In other words, in plan view, the outer edge of the wiring layer 11 coincides with the outer edge of the surrounding portion 9. However, the wiring layer 11 may allow a part of the above three surfaces to be exposed, although such a configuration differs from the illustrated example. For example, a part or the entirety of the outer edge of the wiring layer 11 may be positioned further inward than the outer edge of the surrounding portion 9. Conversely, a part or the entirety of the outer edge of the wiring layer 11 may be positioned further outward than the outer edge of the surrounding portion 9.

The wiring layer 11 includes, for example, an insulating base member 49 and various conductors disposed in the insulating base member 49. The various conductors include, for example, the aforementioned external terminals 5, and includes second via conductors 51 that connect the external terminals 5 and the chip terminals 13 to each other. In addition, although not particularly illustrated, the conductor of the wiring layer 11 may include, for example, a conductor layer that is positioned in the insulating base member 49 and that is parallel to the D1-D2 plane and/or a conductor layer that overlaps the upper surface of the insulating base member 49.

The thicknesses of the wiring layer 11 and the like may be set in any appropriate manner. For example, in a case where the thicknesses are comparatively small, the distance from the upper surface 19a of the cover 19 to the upper surface of the wiring layer 11 (in the illustrated example, the upper surface of the external terminal 5) or to the upper surface of the insulating base member 49 may be less than or equal to 2 times, 1.5 times, or 1 time the thickness of the cover 19 (the sum of the thicknesses of the frame portion 41 and the cover portion 43, the same applies to the following part of the present paragraph). Alternatively, the thickness of the wiring layer 11 (in the illustrated example, the distance from the lower surface of the insulating base member 49 to the upper surface of the external terminal 5) or the thickness of the insulating base member 49 may be less than or equal to 2 times, 1.5 times, or 1 time the thickness of the cover 19. In a case where the distance or thickness in the D3 direction described above differs in accordance with a position in plan view, for example, the maximum value may be utilized as a comparison target.

### Insulating Base Member

The insulating base member 49 may be composed of a plurality of layers (illustrated example), or may be formed of one layer. When the insulating base member 49 includes a plurality of layers, conductor layers (not illustrated) may be disposed between the plurality of layers. The plurality of layers included in the insulating base member 49 may be made of the same material or may be made of materials that are different from each other. The thickness of the insulating base member 49 and the thickness of each of the plurality of layers of the insulating base member 49 may be set in any appropriate manner in view of protection and/or insulation of the chip 3. The material of the insulating base member 49 may be an organic material such as a resin, an inorganic material such as SiO₂, or may be a mixture of an organic material and an inorganic material, such as a resin in which a filer made of an inorganic material is mixed.

In the illustrated example, the insulating base member 49 includes a first insulating layer 53 that overlaps the upper surface of the chip 3 and the upper surface of the surrounding portion 9, and a second insulating layer 55 that overlaps the first insulating layer 53. The first insulating layer 53 and the second insulating layer 55 may be made of materials that are different from each other. For example, the material of the first insulating layer 53 may be an epoxy resin, and the material of the second insulating layer 55 may be a polyimide resin. In this case, for example, the second insulating layer 55 can improve the heat resistance of the insulating base member 49, while the first insulating layer 53 can be easily processed.

The thickness of each of the first insulating layer 53 and the second insulating layer 55 is greater than the thickness of the second conductor layer 25. That is, electrical loss can be reduced by reducing the thickness of the second conductor layer 25 and reducing the distance in the thickness direction.

### External Terminal

The external terminal 5 has an upper surface that is exposed toward the +D3 side. The external terminal 5 may be formed of a conductor layer that is formed on the upper surface of the insulating base member 49, or may be composed of a conductor layer and/or a via conductor that are/is formed in the insulating base member 49 and exposed toward the +D3 side from a hole formed in the insulating base member 49. In the illustrated example, the external terminal 5 is formed of a conductor layer that is formed on the upper surface of the first insulating layer 53 and is exposed toward the +D3 side from a hole (without reference numeral) formed in the second insulating layer 55. To be more specific, a part of the external terminal 5 on the −D3 side (an outer peripheral portion of a third conductor layer 57 described below) is covered by the second insulating layer 55.

The entirety of the external terminal 5 may be made of the same material, or the external terminal 5 may be formed of a combination of a plurality of parts that are made of materials that are different from each other. In the illustrated example, the external terminal 5 includes the third conductor layer 57 that overlaps the upper surface of the first insulating layer 53, and a fourth conductor layer 59 that overlaps the third conductor layer 57. The third conductor layer 57 and the fourth conductor layer 59 are made of, for example, materials that are different from each other.

The third conductor layer 57 may be formed of one metal layer, or may be composed of a plurality of metal layers. Examples of the latter include, although not particularly illustrated, a layer composed of the following: an underlying layer that is positioned on the upper surface of the first insulating layer 53 (excluding a part directly above the second via conductor 51), and a body portion formed on the underlying layer by electric plating or the like. The material (of the entirety of or the body portion) of the third conductor layer 57 may be, for example, as with the second conductor layer 25, a material having a higher electroconductivity (lower electric resistivity) than the material of a main part of the first conductor layer 21 (such as the excitation electrode 17). To be specific, the material may be Cu or an alloy containing Cu as a main component.

The fourth conductor layer 59 may be formed of one metal layer, or may be composed of a plurality of metal layers. As the material of the fourth conductor layer 59, for example, a material that is utilized as a so-called barrier metal may be used. For example, Cr, Au, Ti, and/or Ni may be used. By using such a material, for example, joint strength can be improved and/or generation of an unintended intermetallic compound can be reduced.

The position of the external terminal 5 in plan view may be set in any appropriate manner. For example, in a see-through plan view, the external terminal 5 may be positioned within the chip 3, or a part or the entirety of the external terminal 5 may be positioned outside of the chip 3. In other words, in a see-through plan view, the external terminal 5 need not overlap the surrounding portion 9, or a part or the entirety of the external terminal 5 may overlap the surrounding portion 9. For example, a plurality of external terminals 5 may include those that are arranged along the outer peripheral edge of the upper surface 1a. In this case, the shortest distance between each external terminal 5 and the outer peripheral edge of the upper surface 1a may be, for example, less than or equal to the diameter of the external terminal 5. An external terminal 5 that is positioned farther than such a position from the outer peripheral edge may be provided. For example, in a see-through plan view, the external terminal 5 may overlap the entirety of the second via conductor 51 and/or the chip terminal 13, or need not overlap a part or the entirety of these. For example, in a see-through plan view, a part or the entirety of the external terminal 5 may overlap a part of the space SP, or the entirety of the external terminal 5 need not overlap the space SP.

The number of the external terminals 5 may be set in any appropriate manner in accordance with the circuit configuration of the SAW device 1. The number of the external terminals 5 may be the same as or different from the number of the chip terminals 13. The planar shape of and dimensions of each external terminal 5 may also be set in any appropriate manner. For example, the planar shape of the chip terminal 13 may be a circle.

### Second Via Conductor

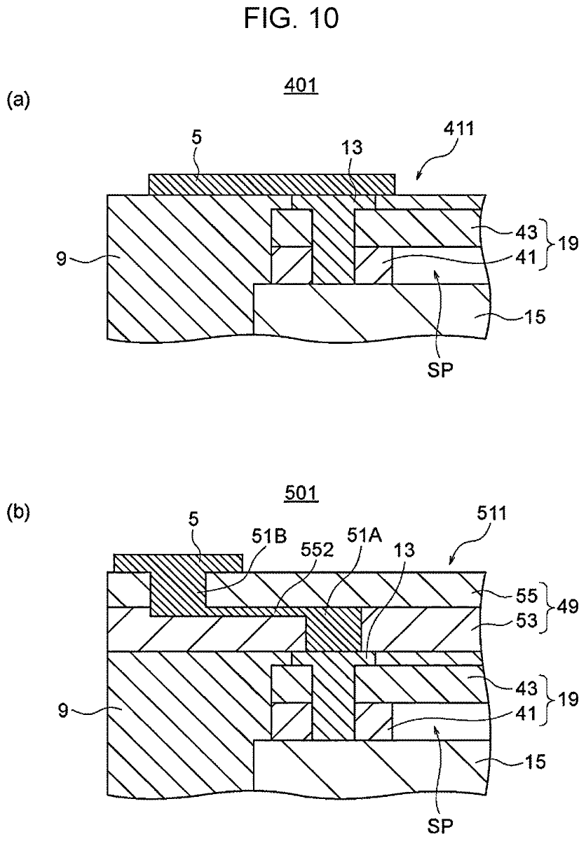

The second via conductor 51 has, for example, a columnar shape extending through at least a part of the thickness of the insulating base member 49, is directly connected to at least one of the chip terminal 13 and the external terminal 5, and contributes to electric connection between these two. In the illustrated example, the second via conductor 51 extends through the first insulating layer 53, and is directly connected to both of the chip terminal 13 and the external terminal 5. Configurations other than the illustrated example will be described below (FIG. 10(b)).

The specific shape and dimensions of each second via conductor 51 may be set in any appropriate manner. For example, the shape of a cross section of the second via conductor 51 parallel to the upper surface 1a may be a circle or an ellipse. For example, the diameter of the second via conductor 51 may be constant or need not be constant in the extension direction. Examples of the latter include a tapered shape, an inversely tapered shape, and/or a shape such that the diameters of a plurality of parts extending through a plurality of insulating layers are different from each other. The dimensions and/or the material of a plurality of second via conductors 51 may be the same as each other or may be different from each other.

The material of the second via conductor 51 may be any appropriate metal. The entirety of the second via conductor 51 may be made of the same material, or parts of the second via conductor 51 may be made of materials that are different from each other. Examples of the latter include a configuration such that the second via conductor 51 includes: an underlying layer formed on an inner surface of a hole of the first insulating layer 53, and a body portion formed by electric plating or the like on the inside of the underlying layer. In this case, only the body portion may be regarded as the second via conductor 51. The material of the second via conductor 51 may be the same as or different from the material of the second conductor layer 25 and/or the material of the third conductor layer 57. The material of the second via conductor 51 may be, for example, as with the third conductor layer 57 and the like, a material having a higher electroconductivity (lower electric resistivity) than the material of a main part of the first conductor layer 21 (such as the excitation electrode 17). To be specific, the material may be Cu or an alloy containing Cu as a main component.

### Material of Conductor from Upper Surface of Cover to External Terminal

As can be understood from the foregoing description, the chip terminal 13 and a conductor of the wiring layer 11 (to be more specific, the second via conductor 51) are directly connected to each other. Accordingly, a joining member made of a low-melting-point metal, such as solder, is not interposed between these two. The term “directly connected” may mean a state in which these two are joined to each other or a state in which these two are only in contact with each other. The low-melting-point metal is, for example, a metal whose melting point is lower than 450° C. It is defined in JIS (Japanese Industrial Standards) Z 3001-3 that solder is a material whose melting point is lower

The above description can be expressed differently as follows. The term “connection conductor 61” refers to a conductor that connects the excitation electrode 17 and the external terminal 5 to each other (such as the wiring 31, the internal terminal 45, the first via conductor 23, the chip terminal 13, and the second via conductor 51). The term “first portion 61a” refers to a part of the connection conductor 61 extending to the external terminal 5 from a position that is closer to the substrate 15 than the upper surface 19a of the cover 19 (such as a part of the first via conductor 23 at least on the +D3 side, the chip terminal 13, and the second via conductor 51). Then, the first portion 61a is made of a material whose melting point is higher than or equal to 450° C. That is, the material whose melting point is higher than or equal to 450° C. is continuously present from a position below the upper surface 19a of the cover 19 to the external terminal 5.

Here, the melting point of a material can be determined, for example, as follows: disassembly and slicing after resin-embedding are performed to exposed a part of the material, composition analysis of the part is performed, and the melting point can be determined from a phase diagram. Alternatively, the melting point can be examined by visual observation by heating a part of the material after disassembly. Further alternatively, a part of the material may be sampled and analyzed by using a melting-point apparatus.

The entirety of the first portion 61a (the underlying layer may be disregarded as described above) may be made of the same material or may be made of materials that are different from each other. In either case, as described above, the material may be, for example, a material having a higher electroconductivity (lower electric resistivity) than the material of the excitation electrode 17, which is selected in consideration of an acoustic viewpoint. To be specific, the material may be Cu or an alloy containing Cu as a main component.

### Details of Thickness of Second Conductor Layer

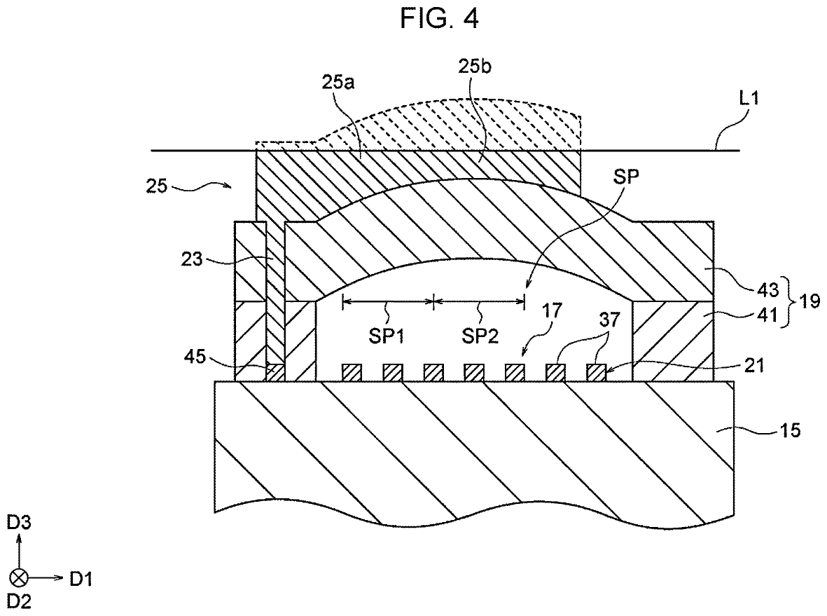

FIG. 4 is a schematic sectional view illustrating a part of the chip 3.

The cover portion 43 is, for example, bent (curved) at least on the space SP toward a side opposite to the space SP (+D3 side). From a different viewpoint, the space SP includes parts whose heights from the substrate 15 are different from each other. Because the cover portion 43 is curved, the lower surface of the second conductor layer 25, which is positioned on the cover portion 43, is curved toward the +D3 side. On the other hand, the upper surface of the second conductor layer 25 is planar, as represented by a straight line LP. From a different viewpoint, the second conductor layer 25 has regions whose thicknesses are different from each other. Here, the term “planar” may mean relatively planar compared with the curvature of the lower surface of the second conductor layer 25, and need not mean strictly planar.

In FIG. 4, the curvature of the cover portion 43, the curvature of the second conductor layer 25, difference in thickness of the second conductor layer 25, and the like are exaggerated. In FIG. 4, an upper part of the second conductor layer 25, when it is assumed that the thickness of the second conductor layer 25 is constant, is represented by a dotted line.

The curvature of the cover portion 43 and the like can be expressed differently as follows. The space SP includes, when seen in a normal direction of the substrate 15 (the D3 direction), a first space portion SP1 that is a part of the space SP1 and a second space portion SP2 that is another part of the space SP. The height of the second space portion SP2 from the substrate 15 to the cover 19 (the cover portion 43) (in the D3 direction) is greater than that of the first space portion SP1. On the other hand, the second conductor layer 25 includes a first region portion 25a that overlaps the first space portion SP1 when seen through in the D3 direction and a second region portion 25b that overlaps the second space portion SP2 when seen through in the D3 direction. The second region portion 25b is thinner than the first region portion 25a.

The difference between the thickness of the first region portion 25a and the thickness of the second region portion 25b may be set in any appropriate manner. For example, in the second conductor layer 25, the difference between the thickness of the thickest part and the thickness of the thinnest part is greater than or equal to 1/10, ⅕, or ⅓ of the thickness of the thickest part and less than or equal to ⅔ or ⅓ of the thickness of the thickest part. These lower limits and upper limits may be used in any combination unless contradiction arises.

### Examples of Dimensions

Hereafter, examples of the dimensions of various members will be described. The dimensions listed here are only examples, and actual dimensions may be greater than or less than the ranges described below.

The thickness of the frame portion 41 in the D3 direction (from a different viewpoint, the minimum height of the space SP) and the thickness of the cover portion 43 (in the D3 direction) each may be, as described above, greater than or equal to 5 μm and less than or equal to 30 μm, or may be less than or equal to 20 μm. The thickness of the frame portion 41 in plan view (in the D1 direction, the D2 direction, or the like) may be, in the thinnest part, greater than or equal to 5 μm and less than or equal to 30 μm, or may be less than or equal to 20 μm. The maximum value or the minimum value of the thickness of the second conductor layer 25, from a different viewpoint, the distance from the cover 19 to the wiring layer 11 (the first insulating layer 53) may be greater than or equal to 10 μm and less than or equal to 20 μm. The thickness of the insulating base member 49 or the first insulating layer 53 may be greater than or equal to 10 μm and less than or equal to 30 μm. The diameter of the second via conductor 51 (the maximum diameter in a case of a non-circular shape) may be greater than or equal to 15 μm and less than or equal to 20 μm. The distance from the upper surface 19a of the cover 19 to the upper surface of the insulating base member 49 may be greater than or equal to 20 μm and less than or equal to 50 μm or 40 μm.

### Method of Manufacturing SAW Device

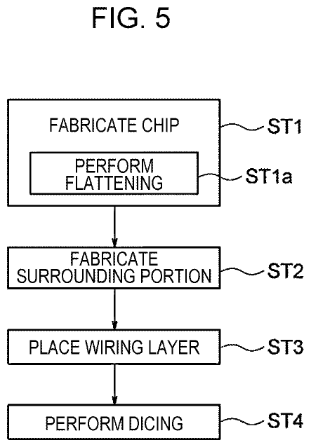

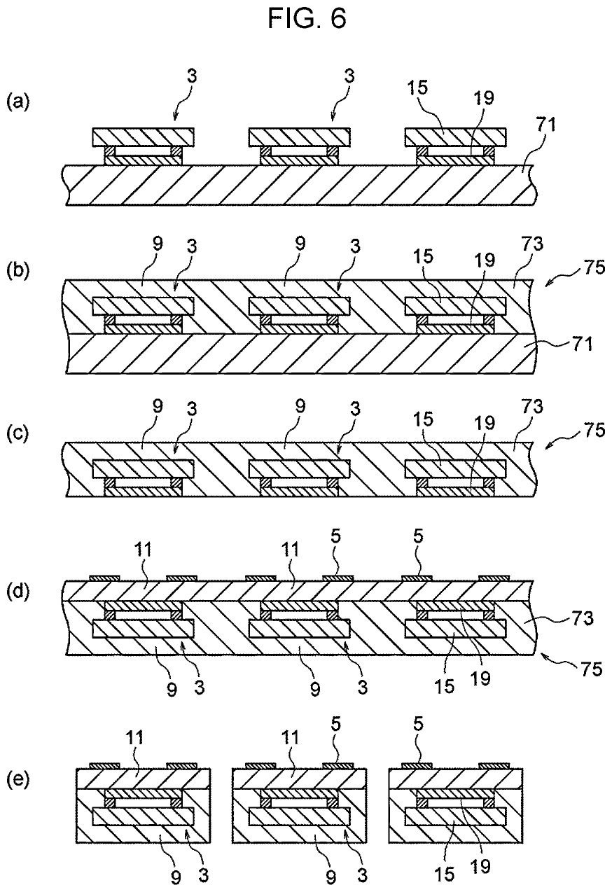

FIG. 5 is a flowchart illustrating an example of steps of a method of manufacturing the SAW device 1. FIGS. 6(a) to 6(e) are sectional views supplemental to FIG. 5. The manufacturing process proceeds sequentially from FIG. 6(a) to FIG. 6(e).

In step ST1, the chip 3 is fabricated. A method of fabricating the chip 3 may be, for example, generally similar to a known method of fabricating a SAW chip, excluding a part thereof (step ST1a described below).

For example, although not particularly illustrated, first, a wafer, which is to be divided into a large number of substrates 15, is prepared. The first conductor layer 21 is formed on the wafer by depositing a metal material and by performing patterning. On the first conductor layer 21, the frame portion 41 is formed by forming a resin layer from a thermosetting resin and by performing patterning. The cover portion 43 is formed by superposing a film made of a thermosetting resin on the frame portion 41 and by performing patterning. Subsequently, the first via conductors 23 and the second conductor layer 25 are formed by forming an underlying layer, precipitating a metal material by electric plating, and performing patterning. Subsequently, individual chips 3 are fabricated by dicing the wafer.

The cover portion 43 (and the frame portion 41) is cured by being heated at an appropriate timing. At this time, a gas in the space SP expands, and, by extension, the cover portion 43 may become curved upward as illustrated in FIG. 4. On the other hand, the second conductor layer 25 is formed, for example, with a constant thickness on the cover 19. As a result, as shown by the dotted line in FIG. 4, the second conductor layer 25 also becomes curved upward. Thus, in step ST1a of step ST1, as shown by a line L1 in FIG. 4, the upper surface of the second conductor layer 25 is flattened. Flattening may be performed by, for example, polishing. To be more specific, for example, the upper surfaces of the chips 3 before dicing may be polished by using a chemical mechanical polishing (CMP) device, which is used in semiconductor manufacturing equipment to polish a wafer. The second conductor layer 25 may have a comparatively large thickness before being polished so that the thickness can become close to a design value by being polished.

In step ST2, the surrounding portion 9 is fabricated.

To be specific, first, as illustrated in FIG. 6(a), a supporter 71 is prepared. The supporter 71 is, for example, a member having a flat upper surface and has, for example, a substrate-like shape. Although not particularly illustrated, the supporter 71 includes, for example, a resin sheet to which a tackiness agent is applied, and is supported by a supporting tool (not illustrated). Alternatively, the supporter 71 may be formed by applying an adhesive or a tackiness agent to a flat upper surface of a supporting tool (not illustrated).

Next, the plurality of chips 3 are placed on the supporter 71. The chips 3 are placed, for example, in such a way that the cover 19 side of each chip 3 faces the supporter 71 side (lower side). Although not illustrated in FIG. 6(a), the upper surface of the second conductor layer 25 (surface on the +D3 side) is in close contact with the supporter 71.

Next, as illustrated in FIG. 6(b), a material 73 in an uncured state, which is to become the surrounding portion 9, is supplied onto the supporter 71 and cured. Thus, the surrounding portion 9, in a state before the side surfaces thereof are formed, is fabricated. From a different viewpoint, a wafer 75, including the plurality of chips 3 and the material 73, is formed.

The material 73 may be supplied by using any appropriate method. For example, the material 73 in a liquid state may be supplied by using a dispenser or by screen printing; or a sheet-like member, which is to become the material 73 by being heated, may be placed. The material 73 may be supplied in a vacuum state (to be precise, in a depressurized state), as in vacuum printing. In this case, for example, the probability of formation of bubbles is reduced. Moreover, for example, the material 73 can easily flow into the gap between the supporter 71 and the cover 19 in a region in which the second conductor layer 25 is not disposed.

The material 73 is cured by, for example, heating the material 73 while pressing the material 73. The specific curing method may be any appropriate method. For example, the material 73 may be heated by using a heater (not illustrated) that supports the supporter 71, and/or the material 73 may be pressed by using a die, including a heater, from above.

Subsequently, as illustrated in FIG. 6(c), the supporter 71 is removed from the wafer 75. The supporter 71 may be removed by peeling off the supporter 71, by melting the supporter 71, or by dissolving the supporter 71 in a chemical solution. A surface from which the supporter 71 has been removed may be cleaned and/or ground or polished in any appropriate manner.

In step ST3, the wiring layer 11 is provided. To be specific, as illustrated in FIG. 6(d), the wiring layer 11 is provided on a surface of the wafer 75 from which the supporter 71 has been removed. The wiring layer 11 may be formed by using, for example, a known method such as an additive method or semi-additive method, as in rewiring in a semiconductor device. The wiring layer 11 may be provided by bonding a flexible substrate to the wafer 75. For example, in a state in which a pad that is positioned on a main surface of the flexible substrate is in contact with the chip terminal 13, the flexible substrate may be heated while pressing the flexible substrate toward the wafer 75 to bond an insulator (bonding layer) on the main surface of the flexible substrate to the upper surface 19a of the cover 19.

In step ST4, as illustrated in FIG. 6(e), the wafer 75 is diced into pieces. Thus, individual SAW devices 1 are fabricated. Dicing may be performed by using a known method, for example, a method using a dicing blade or a method using a laser. To be precise, the wiring layer 11 and the surrounding portion 9 are completed as side surfaces thereof are formed in this step.

As described above, in the present embodiment, an elastic wave device (the SAW device 1) includes the substrate 15, the excitation electrode 17, the cover 19, the surrounding portion 9, the wiring layer 11, and the connection conductor 61. The substrate 15 includes the piezoelectric predetermined region 15aa in the first main surface 15a facing one side (+D3 side) in the normal direction of the substrate 15 (the D3 direction). The excitation electrode 17 is positioned on the predetermined region 15aa. The cover 19 covers the excitation electrode 17 and the first main surface 15a from the +D3 side. The surrounding portion 9 covers the side surface of the substrate 15 and the side surface of the cover 19 and has insulating properties. The wiring layer 11 includes the external terminal 5 exposed toward the +D3 side and overlaps the cover 19 and the surrounding portion 9 from the +D3 side. The connection conductor 61 connects the excitation electrode 17 and the external terminal 5 to each other. The connection conductor 61 includes the first portion 61a (the first via conductor 23, the chip terminal 13, and the second via conductor 51) extending to the external terminal 5 from a position that is closer to the substrate 15 (on the −D3 side) than a surface of the cover 19 on the +D side. The first portion 61a has a melting point higher than or equal to 450° C.

Accordingly, for example, compared with a SAW device in which the chip 3 is encapsulated in a resin after mounting the chip 3 on a rigid circuit board, solder (low-melting-point metal) for mounting the chip 3 is not provided between the chip 3 and the circuit board (the wiring layer 11 in the present embodiment). As a result, for example, stress due to change in temperature is reduced, and the reliability of connection between the chip 3 and the wiring layer 11 is improved. For example, compared with a configuration in which solder is interposed between the chip 3 and the wiring layer 11, signal loss can be reduced. For example, an advantage in reduction of profile is obtained, because the thickness of solder is not necessary. Necessity for ensuring a large area for the chip terminal 13 or necessity for providing the chip terminal 13 with a barrier metal in order to increase strength of joint with solder is reduced, and an advantage in reduction of size and simplification can be obtained.

From a different viewpoint, in the present embodiment, a method of manufacturing an elastic wave device (the SAW device 1) includes a chip fabrication step (ST1), a surrounding-portion fabrication step (ST2), and a wiring-layer placement step (ST3). The SAW device 1 includes the chip 3, the surrounding portion 9, and the wiring layer 11. The chip 3 includes the substrate 15, the excitation electrode 17, and the cover 19. The substrate 15 includes the piezoelectric predetermined region 15aa in the first main surface 15a facing one side (+D3 side) in the normal direction of the substrate 15 (the D3 direction). The excitation electrode 17 is positioned on the predetermined region 15aa. The cover 19 covers the excitation electrode 17 and the first main surface 15a from the +D3 side. The surrounding portion 9 covers a side surface of the substrate 15 and a side surface of the cover 19 and has insulating properties. The wiring layer 11 includes the external terminal 5. The external terminal 5 is electrically connected to the excitation electrode 17 and is exposed toward the +D3 side. The wiring layer 11 overlaps the cover 19 and the surrounding portion 9 from the +D3 side. In the chip fabrication step, the chip 3 is fabricated. In the surrounding-portion fabrication step, the surrounding portion 9 is fabricated by placing the insulating material 73 in an uncured state around the chip 3 and curing the material 73 after the chip fabrication step. In the wiring-layer placement step, the wiring layer 11 is provided on the D3 side of the cover 19 and the surrounding portion 9 after the surrounding-portion fabrication step.

Accordingly, for example, the SAW device 1 according to the present embodiment can be realized, and the aforementioned various advantageous effects can be obtained.

For example, in a case where the chip 3 is encapsulated in a resin after the chip 3 has been mounted on the rigid circuit board, a load is applied to the first via conductor 23 when the chip 3 is being mounted. The load is transmitted to the cover 19 and has an effect on the hermeticity of the space SP. The diameter of the first via conductor 23 and the thickness of the cover 19 are set in consideration of such a factor. With the present embodiment, the cover 19 is surrounded by the surrounding portion 9 before the wiring layer 11 is provided, and thus the chip 3 is reinforced and the hermeticity of the cover 19 is improved. Accordingly, for example, it becomes easier to reduce the diameter of the first via conductor 23 and to reduce the thicknesses of the cover portion 43 (in the D3 direction) and the thickness of the frame portion 41 in plan view (in the D1 direction, the D2 direction, or the like). When a transfer mold is not used and vacuum printing is used to form the surrounding portion 9, pressure applied to the cover 19 is reduced, and therefore it becomes further easier to reduce the thickness of the cover portion 43 and the thickness of the frame portion 41 in plan view. When the diameter of the first via conductors 23 can be reduced, for example, the diameter of the internal terminal 45 can also be reduced. As a result, the degree of freedom in design related to the arrangement of conductors on the first main surface 15a is increased.

For example, with a configuration in which the chip 3 is encapsulated in a resin after the chip 3 has been mounted on a circuit board, the circuit board is limited to a rigid circuit board prepared beforehand. With the present embodiment, because the chip 3 is encapsulated in the surrounding portion 9 before the wiring layer 11 is provided, the degree of freedom in the process of disposing the wiring layer 11 is increased. For example, as mentioned above, a process similar to rewiring in a semiconductor device may be performed, or a process of bonding flexible substrates together may be performed. In a case where a manufacturing method according to the present disclosure (having a feature that the wiring-layer placement step is performed after the surrounding-portion fabrication step) is focused, the wiring layer 11 may be provided by placing and mounting the chip 3 on a rigid circuit board by using solder.

As a result of the aforementioned diversification of the process, for example, the degree freedom in design is increased. For example, in a case where the chip 3 is not mounted on a rigid circuit board, the position of the chip terminal 13 need not be a position such that the chip terminal 13 can support the chip 3 stably on the circuit board. As a result, for example, the positions of the plurality of chip terminals 13 (by extension, the first via conductors 23 and the internal terminal 45) need not be highly symmetric (may be asymmetric), and the chip terminals 13 need not be disposed at the four corners of the chip 3. Moreover, increase in degree of freedom in the positions of the chip terminals 13 and the aforementioned reduction in size of each chip terminal 13 lead to increase in degree of freedom in design of the conductor pattern 47. By extension, it becomes easy to form electronic elements (inductors and/or capacitors) by using the conductor pattern 47. Accordingly, for example, while realizing electronic elements with fine patterns by using the conductor pattern 47, the other electronic elements may be realized by using conductors in the wiring layer 11.

In the present embodiment, the cover 19 covers the excitation electrode 17 with the space SP, which is positioned on the excitation electrode 17, therebetween.

With the configuration in which the space SP is formed, the cover portion 43 deforms easily, compared with a configuration in which the cover 19 covers the excitation electrode 17 without the space SP therebetween (this configuration may also be included in the technology according to the present disclosure). By extension, necessity for thickening the cover portion 43 is increased. Accordingly, from a different viewpoint, the aforementioned advantageous effect according the present embodiment in that it is easy to reduce the thickness of the cover portion 43 is effectively obtained.

In the present embodiment, the SAW device 1 further includes the second conductor layer 25 that overlaps the upper surface 19a of the cover 19. The space SP includes the first space portion SP1 that is a part of the space SP when seen in the D3 direction, and the second space portion SP2 that is another part of the space SP when seen in the D3 direction and whose height from the substrate 15 to the cover 19 is greater than that of the first space portion SP1. The second conductor layer 25 includes the first region portion 25a that overlaps the first space portion SP1 when seen through in the D3 direction, and the second region portion 25b that overlaps the second space portion SP2 when seen through in the D3 direction and that is thinner than the first region portion 25a.

In this case, for example, compared with a case where the thickness of the entirety of the second conductor layer 25 is the thickness of the second region portion 25b (such a case may also be included in the technology according to the present disclosure), the mass and/or the volume of the second conductor layer 25 can be ensured in the first region portion 25a. As a result, for example, an effect as a reinforcement layer can be improved, and loss can be reduced by reducing the resistance value of the wiring. That is, strength can be improved by utilizing the height difference in the space SP, and electric characteristics can be improved.

In the present embodiment, the first portion 61a (the first via conductors 23, the chip terminal 13, and the second via conductor 51) are made of the same metal material.

In this case, for example, the strength of joint between the chip terminal 13 and the second via conductor 51 is improved. The probability of generation of stress in the first portion 61a due to change in temperature is also reduced. In a case where the metal material is copper or an alloy containing copper as a main component, the electroconductivity of the first portion 61a is high, and therefore signal loss is reduced.

In the present embodiment, the surrounding portion 9 also covers the second main surface 15b of the substrate 15 facing the −D3 side.

In this case, for example, protection of the substrate 15 is reinforced. For example, when temperature increases and the cover 19 and the insulating base member 49 expand in the D1-D2 plane and apply a stress to the substrate 15, a part of the stress can be cancelled due to expansion of a part of the surrounding portion 9 on the −D3 side in the D1-D2 plane. By extension, the probability of change in SAW transmission characteristics due to unintended stress is reduced.

In the present embodiment, the surrounding portion 9 includes a part that is positioned between the wiring layer 11 and the cover 19.

In this case, for example, the cover portion 43 is reinforced, and the hermeticity of the space SP is improved. Bending deformation of the wiring layer 11 is suppressed, compared with a configuration in which a space (filled with a gas, or in a vacuum state) is formed between the cover 19 and the substrate 15 (this configuration may also be included in the technology according to the present disclosure).

### Multiplexer

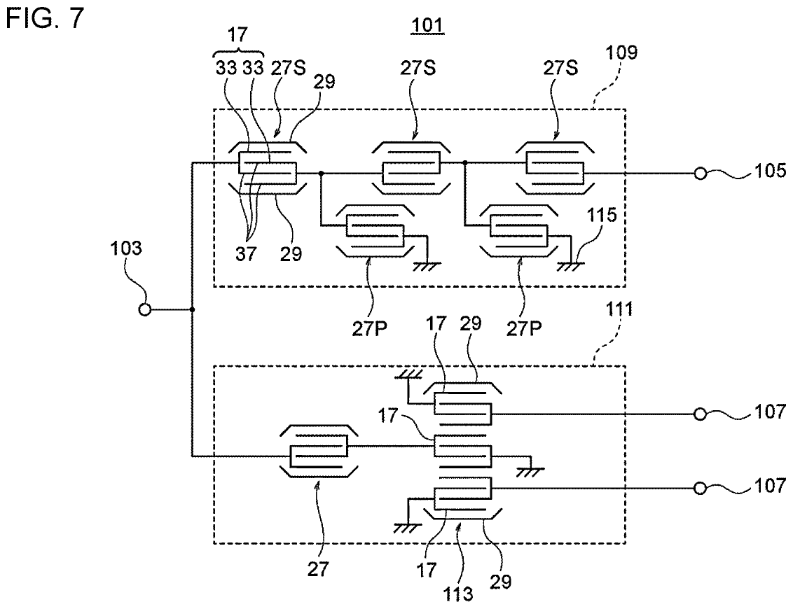

FIG. 7 is a schematic circuit diagram illustrating the configuration of a multiplexer 101 (such as a duplexer), which is an example of the SAW device 1 or an application example of the SAW device 1. As can be understood from reference numerals illustrated in a left upper part of this figure, in this figure, the interdigital electrode 33 is schematically shown in a two-tine fork shape, and the reflector 29 is shown by a line both ends of which are bent.

The multiplexer 101 includes, for example, a transmission filter 109 that filters a transmission signal from a transmission terminal 105 and outputs the filtered transmission signal to an antenna terminal 103, and a reception filter 111 that filters a reception signal from the antenna terminal 103 and outputs the filtered reception signal to a pair of reception terminals 107.

The transmission filter 109 is formed of, for example, a so-called ladder SAW filter. That is, the transmission filter 109 includes, between the transmission terminal 105 and the antenna terminal 103, a plurality of serial resonators 27S that are serially connected to each other (or only one serial resonator 27S), and one or more parallel resonators 27P that connect the serial line and a reference potential portion 115. Each of the serial resonators 27S and the parallel resonators 27P has, for example, a configuration similar to that of the SAW resonator 27, which has been described above with reference to FIG. 3.

The reception filter 111 includes, for example, a SAW resonator 27 and a multi-mode SAW filter 113 that is serially connected to the SAW resonator 27. The SAW filter 113 includes a plurality of (in the illustrated example, three) excitation electrodes 17 that are arranged in the propagation direction of an elastic wave and a pair of reflectors 29 that are disposed on both sides of the excitation electrode 17.

One SAW device 1 may constitute, for example, the entirety of the multiplexer 101. In this case, the antenna terminal 103, the transmission terminal 105, the reception terminal 107, and the reference potential portion 115 are formed of, for example, the external terminals 5. The transmission filter 109 and the reception filter 111 may be, for example, both provided in one chip 3. As described above, one SAW device 1 may include a plurality of SAW chips 3. Accordingly, in one SAW device 1, the transmission filter 109 and the reception filter 111 may be provided in two independent chips 3, or may be distributed in three or more chips 3. One SAW device 1 may constitute only a part of the multiplexer 101. The part of the multiplexer 101 in this case is, for example, the transmission filter 109, the reception filter 111, or each part of these.

FIG. 7 illustrates only an example of the multiplexer 101. For example, as with the transmission filter 109, the reception filter 111 may be formed of a ladder filter. The multiplexer 101 is not limited to a duplexer, and may be a device including three or more filters (such as a triplexer or a quadplexer).

### Communication Apparatus

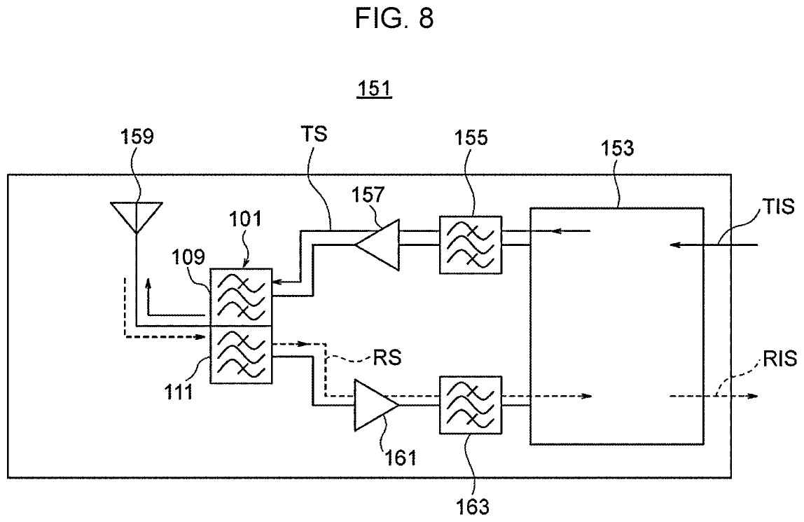

FIG. 8 is a block diagram illustrating a main part of a communication apparatus 151 as an application example of the SAW device 1. The communication apparatus 151 performs wireless communication utilizing a radio wave, and includes the multiplexer 101.

In the communication apparatus 151, a radio frequency integrated circuit (RF-IC) 153 modulates a transmission information signal TIS, including information to be transmitted, and increases the frequency of the signal TIS (converts the signal TIS into a high-frequency signal having a carrier frequency) to form a transmission signal TS. A band pass filter 155 removes unnecessary components outside the transmission pass band from the transmission signal TS, and an amplifier 157 amplifies the transmission signal TS and inputs the transmission signal TS to the multiplexer 101 (the transmission terminal 105). Then, the multiplexer 101 (the transmission filter 109) removes unnecessary components outside the transmission pass band from the input transmission signal TS, and outputs the transmission signal TS, after the removal, from the antenna terminal 103 to an antenna 159. The antenna 159 converts the input electric signal (transmission signal TS) into a wireless signal (radio wave), and transmits the wireless signal.

In the communication apparatus 151, the antenna 159 converts a wireless signal (radio wave) received by the antenna 159 into an electric signal (reception signal RS), and inputs the electric signal to the multiplexer 101 (the antenna terminal 103). The multiplexer 101 (the reception filter 111) removes unnecessary components outside the reception pass band from the input received signal RS, and outputs the received signal RS from the reception terminal 107 to an amplifier 161. The amplifier 161 amplifies the output reception signal RS, and a band pass filter 163 removes unnecessary components outside the reception pass band from the reception signal RS. The RF-IC 153 reduces the frequency of the reception signal RS and demodulates the reception signal RS to form a reception information signal RIS.

The transmission information signal TIS and the reception information signal RIS each may be a low-frequency signal (base-band signal), such as an analog audio signal or a digital audio signal, including any appropriate information. The pass band of a wireless signal may be set in any appropriate manner, and may be set in accordance with any of various known standards. A modulation method may be phase modulation, amplitude modulation, frequency modulation, or a combination of two or more of these. Although a direct conversion method has been described above as an example of a circuit method, any other appropriate method, such as double super heterodyne method, may be used. FIG. 8 schematically illustrates only a main part. A low-pass filter, an isolator, and the like may be added at appropriate positions, and the positions of amplifiers and the like may be changed.

### Modifications

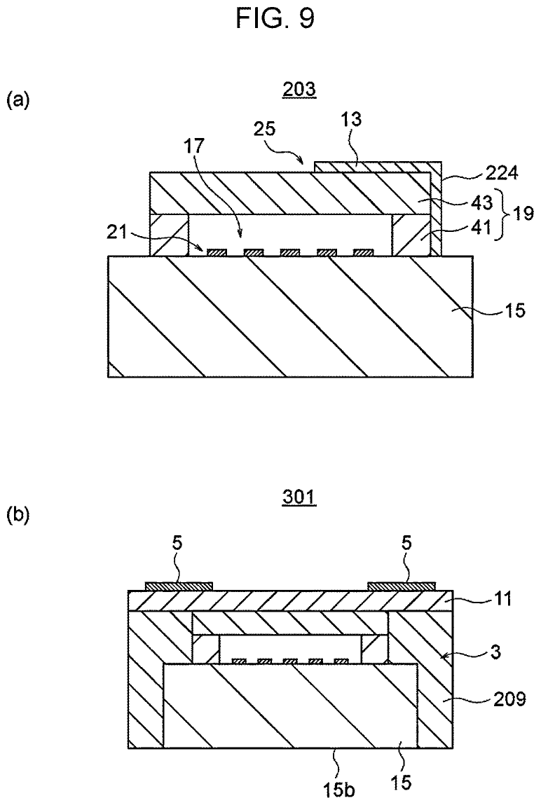

Hereafter, modifications of the SAW device will be described. In the following description, basically, only the differences from the embodiment will be described. Matters that are not particularly mentioned may be regarded as similar to or analogous to those of the embodiment or may be inferred from those of the embodiment. For convenience, members of the modifications corresponding to members of the embodiment may be denoted by the same reference numerals as those of the embodiment even if there are differences between these. FIGS. 9(a) to 10(b) are schematic sectional views illustrating the entirety or a part of SAW devices according to the modifications. In these figures, illustrations of parts for which need for illustration is small regarding the differences from the embodiment are omitted.

### First Modification

FIG. 9(a) illustrates a chip 203 according to a first modification. As with the chip 3 according to the embodiment, the chip 203 forms a SAW device together with the surrounding portion 9 and the wiring layer 11. The chip 203 includes, in addition to or instead of the first via conductors 23 (not illustrated here), a conductor layer 224 that is positioned on a side surface of the cover 19. The conductor layer 224 contributes, for example, to connect the first conductor layer 21 and the second conductor layer 25 to each other.

With the SAW device according to the embodiment, as described above, the diameter of the first via conductor 23 can be reduced and the degree of freedom in position of the internal terminal 45 can be increased, because the need for ensuring the strength of the first via conductors 23 is reduced. For the same reason, the conductor layer 224, instead of the first via conductors 23, can connect the first conductor layer 21 and the second conductor layer 25 to each other as in the present modification. In this case, for example, reduction in size is made easier, and the freedom in design is further increased.

### Second Modification

FIG. 9(b) illustrates a SAW device 301 according to a second modification. In this modification, a surrounding portion 209 does not cover the second main surface 15b of the substrate 15. A method of manufacturing the SAW device 301 is, for example, as follows.

In FIG. 6(a), the chip 3 is placed on the supporter 71 in such a way that the cover 19 side faces downward (facedown). On the other hand, in the method of manufacturing the SAW device 301, the chip 3 is placed on the supporter 71 in such a way that the cover 19 faces upward (faceup). In other words, the second main surface 15b (or a layer (not illustrated) that covers the second main surface 15b) is brought into close contact with the supporter 71.

Next, as can be inferred from FIG. 6(b), the material 73 in an uncured state, which is to become the surrounding portion 209, is supplied onto the supporter 71 and is cured. At this time, for example, the upper surface of the material 73 is made higher than the upper surface of the chip terminal 13. The material 73 after being cured is polished until the upper surface of the chip terminal 13 becomes exposed. Alternatively, supply of the material 73 may be controlled so that the upper surface of the material 73 in an uncured state is positioned near the upper surface of the chip terminal 13.

Subsequently, steps similar to those in the embodiment may be performed.

### Third Modification

FIG. 10(a) illustrates a part of a SAW device 401 according to a third modification. In this modification, a wiring layer 411 does not include the insulating base member 49. The external terminal 5 is disposed directly on the upper surface of the chip terminal 13 and the upper surface of the surrounding portion 9.

### Fourth Modification

FIG. 10(b) illustrates a part of a SAW device 501 according to a fourth modification. In this modification, a wiring layer 511 includes a conductor layer 552 that is positioned in the insulating base member 49. From a different viewpoint, the wiring layer 511 includes a layer of wiring (the conductor layer 552) that is interposed between the chip terminal 13 and the external terminal 5. To be specific, the wiring layer 511 includes a second via conductor 51A extending through the first insulating layer 53 directly above the chip terminal 13, the conductor layer 552 positioned in the first insulating layer 53 and the second insulating layer 55, and a second via conductor 51B extending through the second insulating layer 55 directly below the external terminals 5. The chip terminal 13 and the external terminal 5 are connected to each other via the second via conductor 51A, the conductor layer 552, and the second via conductor 51B.

The technology according to the present disclosure is not limited to the embodiment described above, and may be carried out in various configurations.

The embodiment and modifications described above may be combined in any appropriate manner. For example, the conductor layer 224 according to the first modification may be incorporated in any of the second to fourth modifications, and the surrounding portion 209 according to the second modification may be incorporated in any of the third and fourth modifications.

The elastic wave is not limited to a SAW. In other words, the elastic wave device is not limited to a SAW device. For example, the elastic wave device may be a BAW device that utilizes a bulk acoustic wave (BAW), a boundary acoustic waves device that utilizes a boundary acoustic wave (which may be regarded as a type of SAW), or a film bulk acoustic resonator (FBAR) having both surfaces of a piezoelectric film as free boundaries. As can be understood from the fact that the elastic wave device may be a film bulk acoustic resonator, an excitation electrode is not limited to an interdigital transducer electrode.

The surrounding portion need not cover a surface of a cover opposite to a substrate (the upper surface 19a). In this case, for example, a wiring layer may directly overlap the upper surface of the cover. The surrounding portion need not cover all of the side surfaces of the cover and the side surfaces of the substrate. The entirety of the surrounding portion need not be integrally formed from the same material. For example, the materials of an upper part and a lower part of the surrounding portion may be different from each other. However, in this case, only a part that is integrally formed from the same material (only one of an upper part and a lower part) may be regarded as the surrounding portion.

In a wiring layer, the number of insulating layers that constitute an insulating base member may be any appropriate number. Likewise, the number of via conductors that extend through the insulating layers and the number of conductor layers that are positioned between the insulating layers may be any appropriate number. For example, the number of insulating layers may be one, as mentioned in the embodiment. In each of the embodiment and modifications, an insulating layer having two layers has been described. However, the insulating layer may have three or more layers. The conductor of the wiring layer may form any appropriate electronic elements, such as inductors and/or capacitors.

The chip need not have a conductor layer (the second conductor layer 25) on the upper surface of the cover. In this case, the chip terminal may be formed of, for example, an upper surface of a via conductor (the first via conductors 23) that extends through the cover. Without providing such a via conductor, a chip in which the internal terminal 45 is exposed toward the +D3 side from a hole of the cover 19 in which the first via conductors 23 is disposed in the embodiment may be used. The cover of the chip is not limited to a cover composed of two layers, and may be a cover composed of three or more layers. The frame portion and the cover portion may be integrally formed from the same material in the manufacturing process.

The first via conductor 23 may have a smaller diameter than the second via conductor 51. In this case, because the first via conductor 23 can be used as an inductor component, a necessary inductor can be formed on a side close to the excitation electrode 17. Moreover, because the area of the first main surface 15a of the substrate 15 can be reduced, reduction in size can be achieved, and a region on which the excitation electrode 17 can be disposed can be enlarged within a limited area.

### REFERENCE SIGNS LIST

1 SAW device (elastic wave device), 3 SAW chip (chip), 9 surrounding portion, 11 wiring layer, 15 substrate, 15a first main surface, 15aa predetermined region, 17 excitation electrode, 19 cover, 61 connection conductor, 61a first portion.

1. An elastic wave device comprising:
a substrate that includes a piezoelectric predetermined region in a first main surface facing one side in a normal direction of the substrate;
an excitation electrode that is positioned on the predetermined region;
a cover that covers the excitation electrode and the first main surface from the one side;
an insulating surrounding portion that covers a side surface of the substrate and a side surface of the cover;
a wiring layer that includes an external terminal exposed toward the one side and that overlaps the cover and the surrounding portion from the one side; and
a connection conductor that electrically connects the excitation electrode and the external terminal to each other and that includes a first portion extending to the external terminal from a position that is closer to the substrate than a surface of the cover on the one side, the first portion having a melting point higher than or equal to 450° C.

2. The elastic wave device according to claim 1, wherein the cover covers the excitation electrode with a space, which is positioned on the excitation electrode, therebetween.

3. The elastic wave device according to claim 2, further comprising:
a conductor layer that overlaps the surface of the cover on the one side,
wherein the space includes
a first space portion that is a part of the space when seen in the normal direction, and
a second space portion that is another part of the space when seen in the normal direction and that has a height, from the substrate to the cover, that is higher than the height of the first space portion, and
wherein the conductor layer includes a first region portion that overlaps the first space portion when seen through in the normal direction, and
a second region portion that overlaps the second space portion when seen through in the normal direction and that is thinner than the first region portion.

4. The elastic wave device according to claim 1, wherein the first portion is made of a same metal material.

5. The elastic wave device according to claim 4, wherein the metal material is copper or an alloy mainly composed of copper.

6. The elastic wave device according to claim 1, wherein the surrounding portion also covers a second main surface of the substrate facing the other side in the normal direction.

7. The elastic wave device according to claim 1, wherein the surrounding portion includes a part that is positioned between the wiring layer and the cover.

8. The elastic wave device according to claim 1, wherein the connection conductor includes a conductor layer that overlaps a side surface of the cover.

9. A method of manufacturing an elastic wave device including a chip, a surrounding portion, and a wiring layer, wherein the chip includes
a substrate that includes a piezoelectric predetermined region in a first main surface facing one side in a normal direction of the substrate,
an excitation electrode that is positioned on the predetermined region, and
a cover that covers the excitation electrode and the first main surface from the one side,
wherein the surrounding portion covers a side surface of the substrate and a side surface of the cover, and has insulating properties, and
wherein the wiring layer includes an external terminal electrically connected to the excitation electrode and exposed toward the one side, and overlaps the cover and the surrounding portion from the one side,
the method comprising:
a chip fabrication step of fabricating the chip;
a surrounding-portion fabrication step of fabricating the surrounding portion by placing an insulating material in an uncured state around the chip and curing the insulating material after the chip fabrication step; and
a wiring-layer placement step of providing the wiring layer on the one side of the cover and the surrounding portion after the surrounding-portion fabrication step.
